(19) United States
(12) Patent Application Publication
(10) Pub. No.: US 2008/0019095 A1
(43) Pub. Date: Jan. 24, 2008

(54) Configurable heat sink with matrix clipping system

(76) Inventor: Kechuan Liu, Weston, FL (US)

Correspondence Address: Mr. Kevin Liu, 197 Alhambra Way, Weston, FL, 33326, US

(21) Appl. No.: 11/492,180

(22) Filed: Jul. 24, 2006

(51) Int. Cl. H05K 7/20

(52) U.S. Cl. 361/704

(57) ABSTRACT

A heat sink apparatus for use with electronic components comprises a base portion and at least a securing portion. The base portion and the securing portion are of unitary construction. The base portion is configured to have at least one receiving aperture and one heat-conducting surface with fins extended from or attached to its opposite surface. The securing portion is a unitary construction which comprises a cam element and spring clip with auto-align and camming mechanism features. The securing portion is configured to have partially constrained with the base portion, and to be slide along the length direction for dynamic location of electronic device on heat sink. The cam element can be rotated about its cylindrical feature axis resiliently to effect an engaged relation to substantially fixedly maintain the electronic component in abutting relation with heat-conducting surface.

### CROSS-REFERENCE TO RELATED APPLICATIONS

None

### STATEMENT REGARDING FEDERAL SPONSORED RESEARCH OR DEVELOPMENT

Not Applicable

### FIELD OF THE INVENTION

This invention generally relates to the art of heat sink assemblies and, particularly, to a heat sink assembly having an embedded camming clip system comprising camming and auto-align mechanisms configured to provide attachment and alignment of electronic components thereto heat sink body without requiring additional separate parts

### BACKGROUND OF THE INVENTION

Heat sinks or heat sink assemblies of a wide variety of designs have been employed to dissipate heat generated by electronic components and devices on printed wiring or circuit boards to prevent the electronic components and devices from failure due to over heating. More than ever before, today's electronic products are reducing the size and cost, increasing power and speed dramatically, and upgrading frequently with new technologies. So that the heat sinks or heat sink assemblies used in electronic packaging must be smaller size, larger surface areas, lower cost, easier assembly and disassembly to meet the trends.

Generally a heat sink is a piece of part made of any thermal conductive materials, such as Copper, Aluminum and Steel, etc. For better performance and more cost effective, a heat sink usually has extended surface areas, called fins, and is made of Aluminum or some other cheap and good thermal conductive materials. A heat sink assembly comprise of at least one heat sink and one or more attachments, such as clip or clamp, adhesive, and/or fasteners, to attach electronic components or devices onto heat sink body, and finally the heat sink assembly to be mounted into a printed wiring or circuit board.

On a typical printed wiring or circuit board, there may be a number of heat generating electronic components or devices. Conventionally a couple of heat sink assemblies may be used and mounted in different orientations using either though-hole or surface mounting technologies depending upon the circuit design, component selection and layout requirements to dissipate the heat. If the electronic product is required for more power dissipation or higher speed, or smaller size, say from 2 U to 1 U high rack mounting equipment, the heat sink on the printed wiring or circuit board may need to be changed in order to meet the size and power density requirement. Thereby the circuit may need to be redesigned and re-laid out.

In order to improve surface areas, ease of assembly and disassembly, and reduce size and cost, more and more heat sink apparatus are constructed unitarily and use clip or clam instead of using threaded fasteners. An example of the latter may be seen in U.S. Pat. No. 6,201,699 and the Max Clip System™ heat sink from AAVID. These extruded heat sinks with clamps are good examples for improving ease of assembly and scalability, but are limited in the size, performance and unitary construction. The clips for attaching electronic components or devices are separated from the heat sink body, and a tool must be used in assembly and/or disassembly operations.

Accordingly, what is needed is in the art of a smaller size, larger surface areas, lower cost, easier assembly/disassembly and unitarily constructed heat sink apparatus which incorporates the clipping and camming mechanism, and be ready for attaching electronic components or devices thereon without the need of using fasteners, tools and fixtures, and being soldered onto printed wring or circuit board without requiring extra parts.

### SUMMARY OF THE INVENTION

A heat sink apparatus for use with electronic components or devices comprises a base portion and at least one security portion. The base portion is configured to have at least one receiving aperture and at least one heat-conducting surface. The base portion further has fins attached to its opposite side of heat-conducting surface. The base portion and the security portion are of unitary and compact construction. The security portion comprises a camming bar and a spring clip. The camming bar is configured to rotate about an axis of the spring clip to effect camming mechanism, and the spring clip has an auto-aligning feature for aligning the electronic component when engaging in assembly. The security portion is configured to flex about its axis resiliently to effect an engaged relation with the heat conducting surface to substantially fixedly maintain the electronic components in abutting relation with the heat dissipating surface. The electronic components can be assembled onto or disassembled from the heat sink assembly easily without the needs of tools and fixtures.

The unitary construction for a heat sink apparatus according to the present invention avoids the necessity for additional assembly parts such as screws, nuts, bolts, washers and adhesives. The heat sink apparatus of the present invention also avoids the requirement for such separate attachments as spring clips and fixtures suitable for clipping mechanism. In such all-in-one solution heat sink apparatus, it greatly reduces the assembly time, documentation and inventory costs.

The unitary construction for a heat sink apparatus according to the present invention provides the maximum flexibility for circuit design and printed circuit or wiring board layouts. The heat sink apparatus of the present invention also provides the flexibility to accommodate the technologies changes in IC packaging.

It is a further object of the present invention to provide a heat sink apparatus that the assembly of security portion and the base portion together to create unitary construction uses the very cost effective operations without requiring expensive equipment, tooling, skilled workers and complicated fixtures. It is, therefore, an object of the present invention to provide a heat sink apparatus that is of unitary construction using cost-effective secondary assembly operations.

It is yet a further object of the present invention to provide a heat sink apparatus that may be assembled with an associated electronic component without unnecessary assembly steps, such as ancillary process operations like drilling or tapping apertures.

It is yet a further object of the present invention to provide a heat sink apparatus that can be mounted (or soldered) onto a printed circuit or wiring board using through-hole technology without the needs to change heat sink fabricating and assembling procedures.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

FIGS. 1A-1B illustrate embodiments of prior art heat sinks.

FIGS. 2 is the perspective drawing of an embodiment of the present invention.

FIGS. 3A, 3B and 3C is a perspective drawing of an embodiment of a camming clip system.

FIGS. 4A and 4B are the projective and partially exploded drawings of views illustrating how the base portion and the security portion assembled together.

FIG. 5A 5B and 5C are the perspective drawings illustrating how to attach electronic components onto the heat sink apparatus of the present invention

### DETAILED DESCRIPTIONS OF THE INVENTION

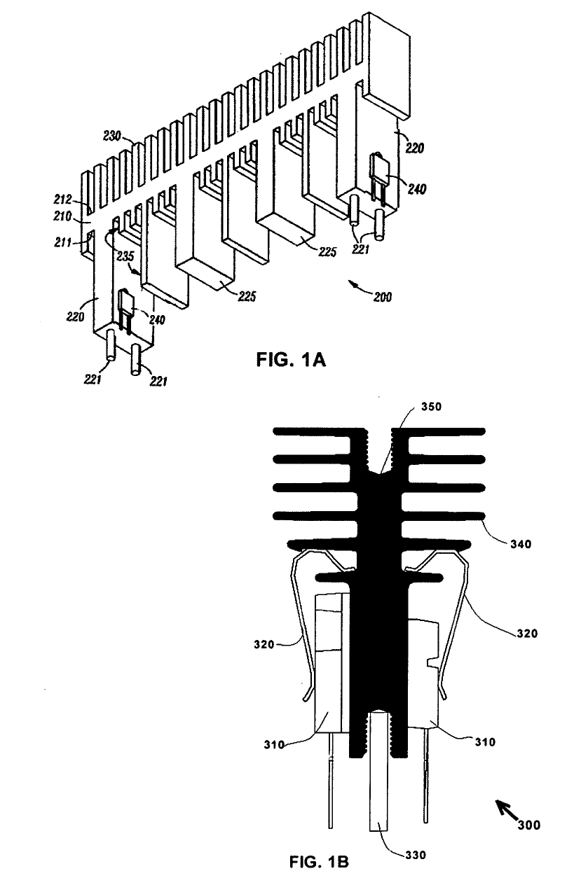

Referring initially to FIGS. 1A and 1B, illustrated are examples of prior art heat sinks 200, 300. The prior art heat sink 200 illustrated in FIG. 1A has a longitudinal spine 210 with an opposing first side 211 and second side 212. Extending from the first side 211 of the spine 210 are electronic device support legs 220, 225, configured so that each leg 220, 225 can support two electronic devices or components on opposing side of the support legs 220, 225, as shown, an electronic component 240 mounted a clip (not shown here), Multiple cooling fins 230, 235 are extending from the second side 212 and first side 211 of the spine 210. Apparently this heat sink has the disadvantages of: 1) fixed position for mounting an electrical component with given printed wiring or circuit layout; 2) lack of unitary construction since the clip is a separated part; and 3) secondary machining operation is required to make the port for receiving pin 221, if the heat sink is manufactured by extrusion; 4) a tool is required for assembly operation. FIG. 1B illustrates another prior art heat sink 300. This heat sink 300 is designed so that heat-generating components 310 are mounted directly to the heat sink body 350 using clips 320. The heat sink 300 can be fastened to a circuit or wiring board by soldering via pin 330. This heat sink 300 also has multiple cooling fins 340 that extend from both sides of the heat sink body 350. FIG. 1B reveals that this heat sink has the disadvantages of: 1) lack of unitary construction since the clip is a separated part; 2) a tool is required for disassembly operation; and 3) clamping force will degrade after number of assembly and disassembly operations, poor repeatability.

It is common practice for a heat sink to be easier for assembling and disassembling electrical components on and to generate constant pressure on the devices. It is highly desirable that a heat sink design be compact, scalable and uniform clipping force while controlling heat from several devices that would otherwise require multiple heat sinks.

It is obvious that a scalable and unitarily constructed heat sink can reduce the part counts in a circuit or wiring board assembly, therefore the cost associated to manufacturing, assembly and parts will be reduced. The present invention addresses the space, weight, flexibility, ease of assembly and cost problems discussed above that are inherent when multiple heat sinks are used, without impairing the ultimate objective of heat control.

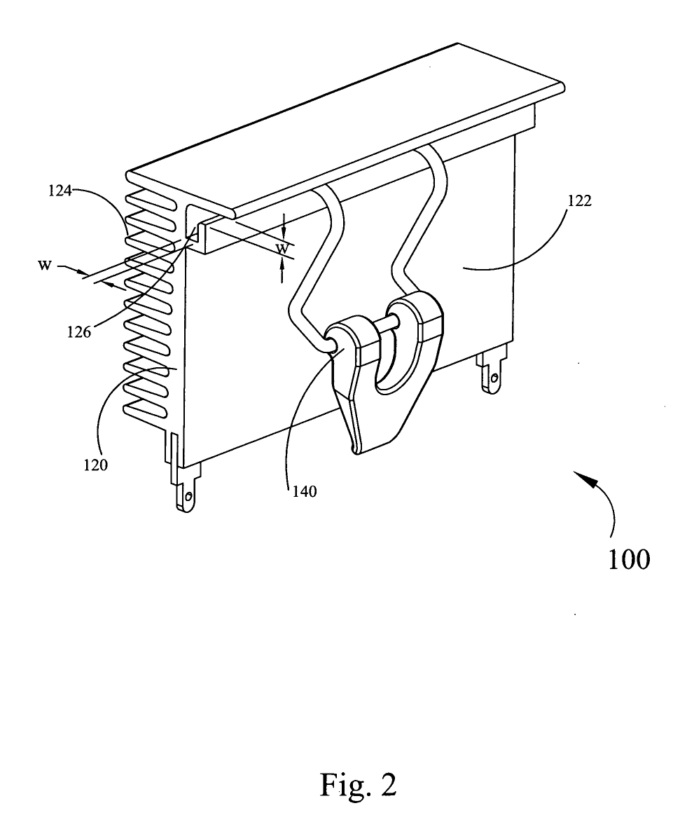

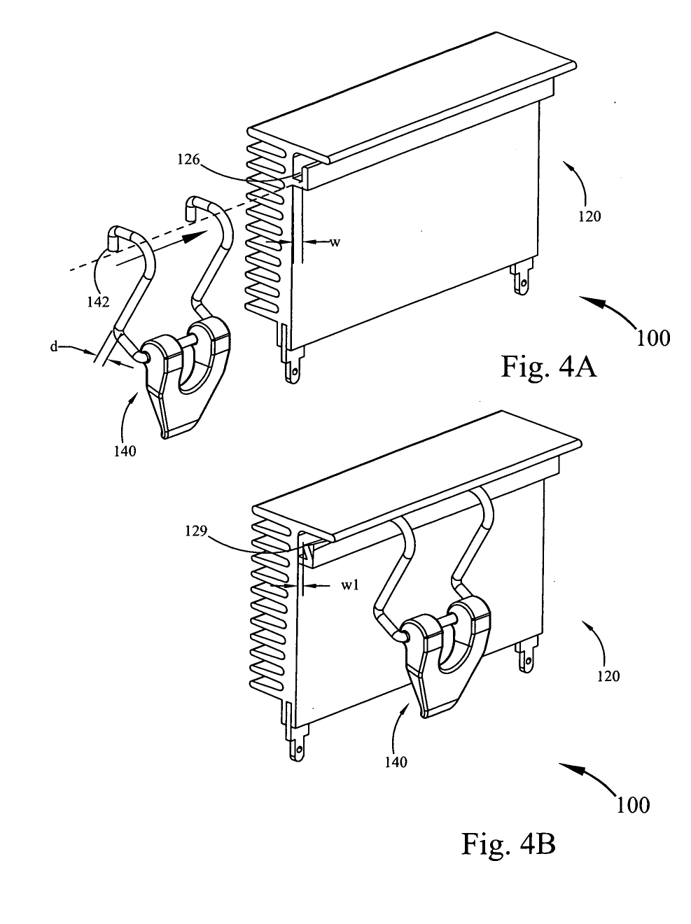

FIG. 2 is the perspective views of a heat sink apparatus constructed according to a preferred embodiment of the present invention. In FIG. 2, a heat sink apparatus 100 comprises a heat sink base member 120 and a camming clip system—the security portion 140. Heat sink base member 120 is configured to have at least one heat interface surface 122 and a plurality of extended surface areas or fins 124 attached or born to the opposite and/or same side of heat interface surface 122 for better heat dissipating, and a L-channel 126 with the width “w”. Heat sink base member 120 is preferably constructed of an inexpensive and better thermal conductive material, such as aluminum, and fabricated by extrusion, casting, machining and the like, preferably extrusion. The fins 124 may be fabricated by extrusion, bonding, brazing, casting, machining or any other manufacturing methods with an inexpensive, better thermal conductive material, such as aluminum. The security portion—camming clip system 140 is configured to be confined within the L-channel 126 of heat sink base member 120 to have to unitary construction, such constrain, according to present invention, may be effected by sliding the camming clip system 140 into L-channel 126 then deforming the both end's edges of L-channel 126 to prevent camming clip system 140 to slide out so as to effect the unitary construction between them, as illustrated in FIG. 4A. The camming clip system 140 comprises of a spring clip 141 and a cam bar 160. Both of them are of unitary construction with the camming mechanism.

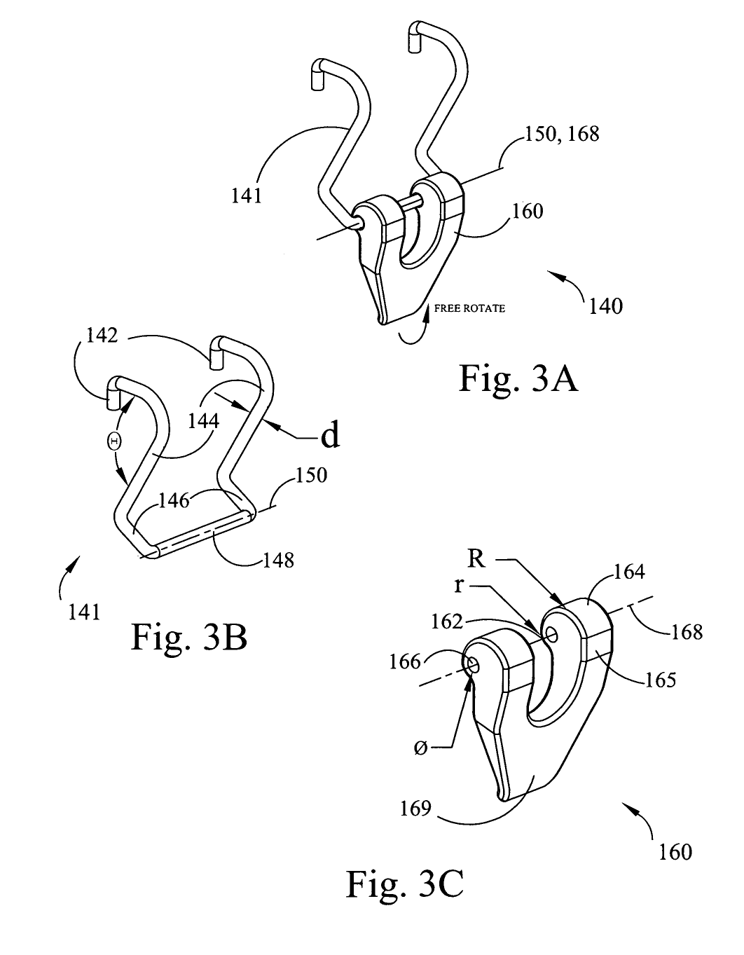

FIG. 3A is a perspective view of the camming clip system 140 constructed according to a preferred embodiment of the present invention. The camming clip system 140 comprises of a spring clip 141 and a cam bar 160. The spring clip 141 may be manufactured from spring wire materials with diameter “d”. As shown in FIG. 3B, the spring clip 141 is configured to be “η” shape-like, having a pair of legs 142, and a pair of curved cantilever arms 144, and a pair of kick legs 146 bridged by a connecting beam 148 having a axis 150. For effective clipping action and sufficient clipping forces, the curved cantilever arm 144 have to be formed with an angle “θ” with leg 142. Those skilled in the art will know the relationship between the clipping force and the angle “θ”. The pair of legs 142 is used for attaching the camming clip system 140 into heat sink base portion 120. The length of the legs 142 should be slight smaller than the height of the L-channel 126 of heat sink 120. The pair of kick legs configured to have auto-aligning mechanism. Connecting beam 146 is configured to server as a shaft for cam bar 160 to rotate on. The axis 150 of the cylindrical connecting beam is co-axial with the axis 168 of receiving hole 166 of cam bar 160 after mating with each other. The cam bar 160 is configured to have a base circle 162 with radius “r”, a clamping circle 164 with radius “R”, a resting flat surface 165, a receiving hole 166 with diameter “φ” having axis 168 and a handle 169. The cam bar 160 may be manufactured from aluminum, plastics or any other cost effective materials by extrusion, casting or injection molding, etc. Cam bar 160 mates with connecting beam 146 of spring clip 140 co-axially to become a unitarily constructed system. Cam bar is freely rotate about its axis 168 to effect the camming mechanism. This unitary construction may be realized with deforming, staking and swaging cam bar 160 or mold in and cast in cam bar 160 into spring clip 140, or other economical means.

FIG. 4A and 4B are a perspective, partially exploded views of the heat sink apparatus according the present invention, showing how to assemble camming clip system 140 onto a heat sink base 120 to effect the unitary connection between them. FIG. 3A shows the camming clip system 140 is sliding into its mating apertures, L-channel 126 on heat sink base 120, since L-channel 126 width is greater than the diameter of spring clip 141 (w>d), so it is easy for the camming clip system 140 with diameter (d) to slide into the L-channel with width (w). FIG. 3B shows the camming clip system 140 is at the positions with heat sink base 120 after sliding in, and the deformation actions are taken to press the edges of the ends 129 to reduce the channel width (w) to (w1) so that w1<d to stop camming clip system 140 sliding out, so as to effect the unitary connection between spring clip 140 and heat sink base 120, in other words, after this operation, spring clip 140 and heat sink base 120 can no longer taken apart from heat sink base 120 without destroying the heat sink assembly 100. Using end cap may also prevent the camming clip system 140 sliding out of the heat sink base 120.

### Operations

In an operation of using this invention, one uses the heat sink apparatus 100 in a normal manner, clamping the electronic components 200 onto the heat sink apparatus 100 and readily places the whole assembly 300 onto a printed circuit or wiring board for soldering operation like any other electronic components. To clamp electronic components onto the heat sink apparatus 100, one should:

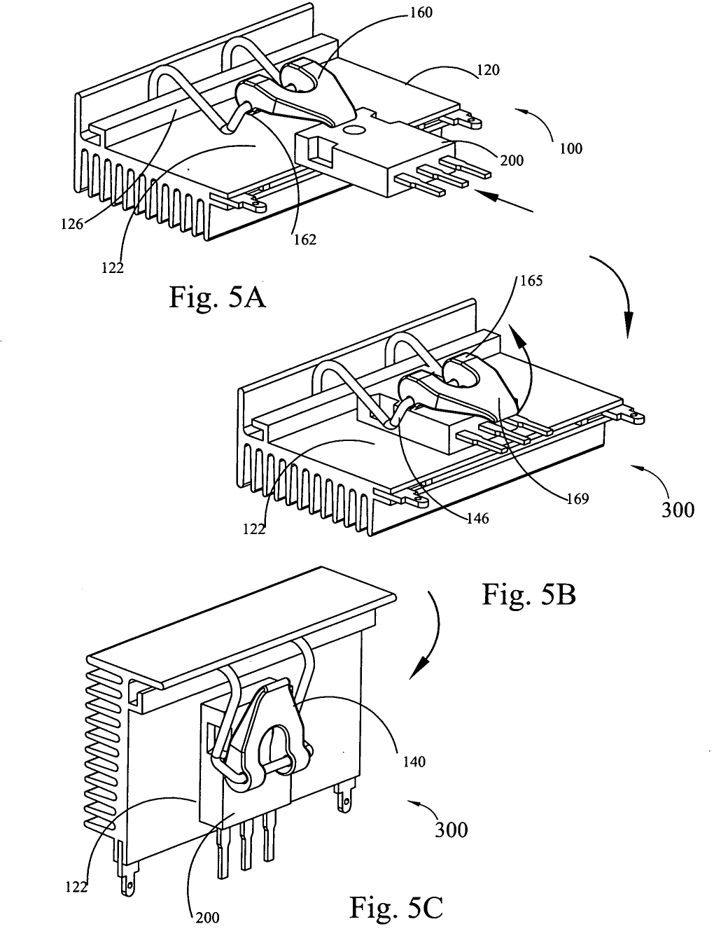

1). Position the cam bar 160 as shown in FIG. 5A, so that the clearance between the cam base circle 162 and the heat dissipating surface 122 is at maximum clearance or gap.

2). Slide an electronic component 200 into the gap until it touch the bottom side of L-channel 126 as shown in FIG. 5A and then rotate the cam handle 169 by 180 degrees so that the flat surfaces 165 rests on top of the component 200, the cam bar 160 will clamp the electronic component 200 against the heat dissipation surface 122 of heat sink base 120 with certain pressure to effect the heat transferring from heat generating electronic component 200 to heat sink 100. Meanwhile the pair of kick legs 146 will constrain and center the electronic component 200 in its position as shown in FIG. 5B. There may be an electrical insulating pad (not shown here) between component 200 and heat dissipation surface 122. The whole heat sink assembly 300 is created and comprises a heat sink apparatus 100 and at least one electronic component 200 as shown in FIG. 5C.

3). After finishing assembling the electronic components or devices onto heat sink, the heat sink assembly 300 is ready for being assembled onto printed circuit or wiring boards 400 (not shown here). One can plug the heat sink assembly 300 into a printed circuit or wiring board for soldering operation, which has been well known as through-hole mounting. Apparently, this heat sink apparatus gives the maximum flexibilities for printed circuit or wiring broad layouts, circuit designs, assembly, disassembly and managing spacing constraints.

Obviously the present invention provides the heat sink apparatus with advantages as listed below:

1). Dynamic locating the electronic device onto the heat sink.

2). Ease of assembly & disassembly

3). Cost effective

4). Ease of manufacturing

Although only a few embodiments of the present invention have been described, it should be understood that the present invention be embodied in many other specific forms without departing from the spirit or the scope of the present invention. The present examples are to be considered as illustrative and not restrictive, and the invention is not to be limited to the details given herein, but may be modified within the scope of the appended claims along with their full scope of equivalents.

I claim:

1. A heat sink apparatus for use with at least one electronic component; the apparatus comprising:
(a) a base portion; and
(b) a securing portion;
said base portion and said securing portion being of unitary construction; said securing portion is partially constrained with said base portion and configured to flex about at one axis resiliently to effect an engaged relation with said base portion; said base portion and said securing portion cooperating in said engaged relation to substantially fixedly maintain said at least one electronic component in abutting relation with said base portion;

2. A heat sink apparatus for use with at least one electronic component as recited in claim 1 wherein said base portion comprising at least one heat conducting surface, at least one receiving aperture and a plurality of extended surface areas or fins;

3. A heat sink apparatus for use with at least one electronic component as recited in claim 2 wherein said heat conducting surface having at least a certain smooth area for electronic component to contact with thereon;

4. A heat sink apparatus for use with at least one electronic component as recited in claim 3 wherein said heat conducting surface usually having fins attached or born thereto its opposite side;

5. A heat sink apparatus for use with at least one electronic component as recited in claim 2 wherein said receiving aperture is a L-channel with an openings on both ends and said heat conducting side;

6. A heat sink apparatus for use with at least one electronic component as recited in claim 5 wherein said L-channel having a width of “w”;

7. A heat sink apparatus for use with at least one electronic component as recited in claim 1 wherein said securing portion configured to be unitary construction of a spring wire clip and camming bar. Where said spring wire clip comprising a pair of legs, and a pair of curved cantilever arms, and a pair of kick arms and connected by a clamping beam or beam thereon which said camming bar to be attached.

8. A heat sink apparatus for use with at least one electronic component as recited in claim 7 wherein said camming bar and said beam of said spring clip have co-axis in assembly.

9. A heat sink apparatus for use with at least one electronic component as recited in claim 8 wherein said camming bar must be able to rotate freely about said co-axis with said beam of said spring clip.

10. A heat sink apparatus for use with at least one electronic component as recited in claim 7 wherein said pair of legs formed with spring wire with diameter “d” which is slightly smaller than said L-channel width “w”.

11. A heat sink apparatus for use with at least one electronic component as recited in claim 7 wherein said curved cantilever arms having to be formed with an angle “θ” with said leg.

12. A heat sink apparatus for use with at least one electronic component as recited in claim 7 wherein said camming bar and spring clip are unitarily constructed.

13. A heat sink apparatus for use with at least one electronic component as recited in claim 7 wherein said kick legs configured to have the auto-aligning mechanism.

14. A heat sink apparatus for use with at least one electronic component as recited in claim 1 wherein said securing portion configured to cooperatively engage a corresponding said receiving aperture (L-channel) in said base portion so that said curved cantilever arms of said spring clip is able to swing about one axis; therefore said connecting beam of said curved cantilever arm to substantially fixedly maintain said at least one electronic component in abutting relation with said heat conducting surface area after said camming bar executes the camming mechanism;

15. A heat sink apparatus for use with at least one electronic component; the apparatus comprising:
(a) a base portion; and
(b) a securing portion;
said base portion and partially constraining said securing portion with said base portion; said base portion and said securing portion being of unitary construction; said securing portion partially constrained inside of said base portion and configured to flex about at least one axis resiliently to effect an engaged relation with said base portion; said base portion and said securing portion cooperating in said engaged relation to substantially fixedly maintain said at least one electronic component in abutting relation with said base member; said means for said unitary construction of said base portion and said securing portion being very economical;

16. A heat sink apparatus for use with at least one electronic component as recited in claim 14 wherein said economic means including machineless and fixtureless assembly operations;

17. A heat sink apparatus for use with at least one electronic component as recited in claim 14 wherein said assembly operations including deforming, half-sheared, staking and swaging, etc;

18. A heat sink apparatus for use with at least one electronic component; the apparatus comprising:
(a) a base portion;
(b) a securing portion;
(c) means for joining said securing portion inside said base portion and for joining said cam bar onto said spring clip; and
(e) means of being dynamic locating;
said base portion and said securing portion being of unitary construction; said securing portion partially constrained with said base portion and configured to flex about at least one axis resiliently to effect an engaged relation with said base portion; said base portion and said securing portion cooperating in said engaged relation to substantially fixedly maintain said at least one electronic component in abutting relation with said base frame; said cam bar and said spring clip being of unitary construction. Said cam bar being rotated freely about said co-axis of said receiving cylindrical aperture and round beam to effect the clamping mechanism, said means for said unitary constructions of said base portion and said securing portion and said cam bar and spring clip being very economical;

19. A heat sink apparatus for use with at least one electronic component as recited in claim 17 wherein said means of being dynamic locating is that the position of electronic device is changeable.

20. A heat sink apparatus for use with at least one electronic component as recited in claim 19 wherein said means of being dynamic locating being made possible by the cooperation of said securing portion and said base portion.
